(19) United States
(12) Patent Application Publication
(10) Pub. No.: US 2023/0045841 A1
(43) Pub. Date: Feb. 16, 2023

(54) SEMICONDUCTOR DEVICE AND METHOD OF MANUFACTURING A SEMICONDUCTOR DEVICE

(71) Applicant: Infineon Technologies AG, Neubiberg (DE)

(72) Inventor: Andreas Voerckel, Finkenstein (AT)

(21) Appl. No.: 17/883,716

(22) Filed: Aug. 9, 2022

(30) Foreign Application Priority Data
Aug. 13, 2021 (DE) 102021121138.7

(51) Int. Cl. H01L 29/78; H01L 29/16; H01L 29/10; H01L 29/66; H01L 29/423; H01L 21/04

(52) U.S. Cl. CPC H01L 29/7813; H01L 29/1608; H01L 29/1095; H01L 29/66068; H01L 29/4236; H01L 21/0465

(57) ABSTRACT

A semiconductor device includes a transistor. The transistor may include a gate electrode in gate trenches formed in a first portion of a silicon carbide substrate and extending in a first horizontal direction. The gate trenches pattern the first portion into ridges. The transistor may further include a source region, a channel region, and a drift region. The source region, channel region and part of the drift region may be arranged in the ridges. A current path from the source region to the drift region may extend in a depth direction of the silicon carbide substrate. The transistor may further include a body contact portion arranged in a second portion of the silicon carbide substrate. The second portion is adjacent to the first portion and extends in a second horizontal direction intersecting the first horizontal direction.

### TECHNICAL FIELD

Examples of the present disclosure relate to semiconductor devices, in particular to semiconductor devices comprising components formed in a silicon carbide substrate, and to a method of manufacturing the semiconductor device.

### BACKGROUND

Semiconductor devices based on silicon carbide (SiC) benefit from the high bandgap and the high breakdown strength of silicon carbide (SiC). However, interfaces between a silicon carbide body and a dielectric layer include a high number of interface states, which may be occupied or not occupied by charge carriers. Along the gate dielectric of a SiC MOSFET (SiC Metal Oxide Semiconductor Field Effect Transistor) the interface states may be occupied by more or fewer charge carriers depending on the operating state of the SiC MOSFET. The number of charge carriers that occupy the interface states influence the mobility and the concentration of free charge carriers that form the field-controlled transistor channel in the on-state of the SiC MOSFET. Moreover, the high breakdown strength of SiC is usually not fully utilized since the field strength occurring in the gate dielectric and the reliability of the gate dielectric often limit the dielectric strength of the SiC MOSFET.

The present application is directed to a semiconductor device that may utilize the beneficial effects of silicon carbide to a high degree.

### SUMMARY

An example of the present disclosure relates to a semiconductor device comprising a transistor. The transistor may comprise a gate electrode arranged in gate trenches formed in a first portion of the silicon carbide substrate and extending in a first horizontal direction. The gate trenches may pattern the first portion of the silicon carbide substrate into ridges. The transistor may further comprise a source region of a first conductivity type, a channel region of a second conductivity type, and a drift region of the first conductivity type. The source region, the channel region and a part of the drift region may be arranged in the ridges. A current path from the source region to the drift region may extend in a depth direction of the silicon carbide substrate. The transistor may further comprise a body contact portion of the second conductivity type that may be arranged in a second portion of the silicon carbide substrate. The second portion may be adjacent to the first portion. The second portion may extend in a second horizontal direction intersecting the first horizontal direction. The body contact portion may be electrically connected to the channel region. The body contact portion may extend in the depth direction of the silicon carbide substrate to a portion below a bottom side of the gate trenches and may be directly adjacent to the drift region.

Another example of the present disclosure relates to a method of manufacturing a semiconductor device comprising a transistor. The method may comprise forming gate trenches in a first portion of the silicon carbide substrate. The gate trenches may extend in a first horizontal direction and may pattern the first portion of the silicon carbide substrate into ridges. The method may further comprise forming a gate electrode in the gate trenches and forming a source region of a first conductivity type, a channel region of a second conductivity type and a drift region of the first conductivity type. The source region, the channel region and a part of the drift region may be formed in the ridges. A current path from the source region to the drift region may extend in a depth direction of the silicon carbide substrate. The method may further comprise forming a body contact portion of the second conductivity type in a second portion of the silicon carbide substrate, the second portion being adjacent to the first portion. The second portion may extend in a second horizontal direction. The method may further comprise electrically connecting the body contact portion to the channel region. The body contact portion may be formed so as to extend in the depth direction of the silicon carbide substrate to a portion below a bottom side of the gate trenches and so as to be directly adjacent to the drift region.

Another example of the present disclosure relates to a semiconductor device comprising a transistor. The transistor may comprise a gate electrode arranged in gate trenches formed in a silicon carbide substrate and extending in a first horizontal direction. The gate trenches may pattern the silicon carbide substrate into ridges. The transistor may further comprise a source region of a first conductivity type, a channel region of a second conductivity type, a drift region of the first conductivity type, and a drain region of the first conductivity type. The source region may be arranged at a first main surface of the ridges. The drain region may be arranged at a second main surface of the silicon carbide substrate. The transistor may further comprise a body contact portion of the second conductivity type that may be arranged in a portion of the silicon carbide substrate extending in a second horizontal direction intersecting the first horizontal direction. The body contact portion may be electrically connected to the channel region. The body contact portion may extend in a depth direction of the silicon carbide substrate to a portion below a bottom side of the gate trenches and may be directly adjacent to the drift region.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the embodiments and are incorporated in and constitute a part of this specification. The drawings illustrate embodiments of a silicon carbide device and a method of manufacturing a silicon carbide device and together with the description serve to explain principles of the embodiments. Further embodiments are described in the following detailed description and the claims.

FIG. 1A shows a schematic cross-sectional view of a semiconductor device according to an example.

FIG. 1B shows a horizontal cross-sectional view of the semiconductor device shown in FIG. 1A.

FIG. 2A shows a horizontal cross-sectional view of a portion of another example of a semiconductor device.

FIG. 2B shows a vertical cross-sectional view of a portion of a further example of a semiconductor device.

FIGS. 2C and 2D show cross-sectional views of other examples of a semiconductor device.

FIG. 2E shows details of a further example of a semiconductor device.

FIG. 2F shows a further detail of an example of a semiconductor device.

FIG. 3A shows a cross-sectional view of another example of a semiconductor device.

FIG. 3B shows a layout view of the semiconductor device shown in FIG. 3A.

FIG. 3C shows a further cross-sectional view of the example shown in FIG. 3A.

FIG. 3D shows a cross-sectional view of another example of a semiconductor device.

FIGS. 4A and 4B show cross-sectional views of a workpiece when performing a method according to an example.

FIGS. 5A to 5G illustrate cross-sectional views of a workpiece when performing an example of a patterning process.

FIGS. 6A to 6D illustrate cross-sectional views of a workpiece when performing further processing steps of a method according to an example.

FIGS. 7A to 7D illustrate cross-sectional views of a workpiece when performing a method according to a further example.

FIGS. 8A to 8D illustrate layout views of a workpiece when performing processing steps according to an example.

FIGS. 9A and 9B summarize methods according to examples.

### DETAILED DESCRIPTION

In the following detailed description, reference is made to the accompanying drawings, which form a part hereof and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language, which should not be construed as limiting the scope of the appending claims. The drawings are not scaled and are for illustrative purposes only. For clarity, the same elements have been designated by corresponding references in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

Ranges given for physical dimensions include the boundary values. For example, a range for a parameter y from a to b reads as a≤y≤b. A parameter y with a value of at least c reads as c≤y and a parameter y with a value of at most d reads as y≤d.

The term “on” is not to be construed as meaning only “directly on”. Rather, if one element is positioned “on” another element (e.g., a layer is “on” another layer or “on” a substrate or semiconductor body), a further component (e.g., a further layer) may be positioned between the two elements (e.g., a further layer may be positioned between a layer and a substrate if the layer is “on” said substrate).

Throughout the present specification elements of transistor cells of a field effect transistor are described. Generally, the field effect transistor may comprise a plurality of transistor cells that are connected in parallel. For example, each single transistor cell may comprise a single gate electrode, a single channel region and further components. The gate electrodes of the single transistor cells may be connected, e.g. electrically connected and/or formed of the same materials. For example, the gate electrodes of the single transistor cells may be connected to a common terminal, e.g. a gate terminal. Further components of the single transistor cells, e.g. the source regions may be respectively connected to a common source terminal. Still further components of the single transistor cells, e.g. the drift region, may be shared among at least some of the transistor cells. The present specification mainly describes the function and structure of the single transistor cells. As is to be readily understood, this description may likewise apply to the further single transistor cells. Descriptions merging the general elements of the transistor and the structural implementation by means of elements of the single transistor cells such as “a gate electrode arranged in gate trenches” are intended to mean that single gate electrodes of respective transistor cells are arranged in respective gate trenches.

An example of a semiconductor device comprising a transistor may comprise a gate electrode arranged in gate trenches formed in a first portion of a silicon carbide substrate and extending in a first horizontal direction.

According to an example, the silicon carbide substrate may have a hexagonal crystal lattice with a c-plane and further main planes. The further main planes may include a-planes or m-planes.

The material of the silicon carbide substrate may be crystalline silicon carbide of any hexagonal polytype, e.g., 2H—SiC, 4H—SiC or 6H—SiC, by way of example. In addition to the main constituents silicon and carbon, the silicon carbide body may include dopants, for example nitrogen N, phosphorus P, beryllium Be, boron B, aluminum Al, and/or gallium Ga. The silicon carbide substrate may include further impurities, for example hydrogen, fluorine and/or oxygen. The silicon carbide substrate may include or consist of a silicon carbide layer grown by epitaxy.

The silicon carbide substrate may have two essentially parallel main surfaces of the same shape and size and a lateral surface area connecting the edges of the two main surfaces. For example, the silicon carbide substrate may have the shape of a polygonal (e.g., rectangular or hexagonal) prism with or without rounded edges, a right cylinder or a slightly oblique cylinder, wherein some of the sides may lean at an angle of at most 8°, at most 5° or at most 3°.

A first main surface at a front side of the silicon carbide substrate may be planar or ribbed. A mean surface plane of the first main surface extends along the horizontal directions. The mean surface plane of a planar first main surface is identical with the planar first main surface. The mean surface plane of a ribbed first main surface is defined by the planar least squares plane of the ribbed first main surface. Position and orientation of the planar least squares plane are defined such that the sum of the squares of the deviations of surface points of the ribbed first main surface from the planar least squares plane has a minimum.

The silicon carbide substrate may horizontally extend along a plane spanned by the horizontal directions. Accordingly, the silicon carbide body may have a surface extension along two horizontal directions and may have a thickness along a vertical direction perpendicular to the horizontal directions. In other words, the vertical direction is parallel to a surface normal onto the mean surface plane.

The terms “first horizontal direction” and “second horizontal direction” define intersecting horizontal directions. Although some of the figures show—by way of illustration—the x-direction and the y-direction as examples of the first and the second horizontal directions, it is clearly to be understood, that the first horizontal direction and the second horizontal direction do not need to be perpendicular to each other. The term “depth direction” defines a direction having a component perpendicular to the mean surface plane. The term “depth direction” encompasses the vertical direction and any other direction different from a horizontal direction.

The c-plane is a {0001} lattice plane. The further main planes may include a-planes ({11-20} family of lattice planes) and m-planes ({1-100} family of lattice planes). The a-planes include the six differently oriented lattice planes (11-20), (1-210), (−2110), (−1-120), (−12-10), and (2-1-10). The m-planes include the six differently oriented lattice planes (1-100), (10-10), (01-10), (−1100), (−1010), and (0-110).

The mean surface plane of the silicon carbide substrate may be tilted to the c-plane by an off-axis angle. In other words, the c-axis may be tilted to the vertical direction by the off-axis angle. The off-axis angle may be in a range from 2 degrees to 8 degrees, for example in a range from 3 degrees to 5 degrees. In particular, the off-axis angle may be approximately 4 degrees. For example, the c-axis may be tilted such that a plane spanned by the vertical direction and the c-axis is parallel to the <11-20> direction. According to another example, the c-axis may be tilted such that a plane spanned by the vertical direction and the c-axis is parallel to the <1-100> direction. At the back side of the silicon carbide substrate, a second main surface of the silicon carbide substrate may extend parallel or approximately parallel to the mean surface plane at the front side.

The silicon carbide substrate may include a columnar portion with column sidewalls. The number of the column sidewalls may be four, five or six, by way of example. In some examples, the shape of the columnar portion may be or may approximate a prism or a pyramid (e.g., a right prism, an oblique prism, a truncated pyramid, a truncated prism; or a combination of such shapes, e.g. a combination of a right prism and a truncated pyramid or a combination of two truncated pyramids), for example with a polygonal base area, typically in the shape of a regular polygon, with four, five or six sides. However, other shapes of the base area may be possible, for example a non-regular polygon (e.g., a trapezoid-like shape or a non-regular triangle) or even an elliptical (e.g. a circular) shape. Neighboring column sidewalls (if applicable) may be connected via joining edges.

The joining edges may run parallel to each other. Alternatively, at least one of the joining edges may have another tilt angle to the vertical direction than at least one other joining edge. For example, a first joining edge may be tilted to the vertical direction by a first vertical tilt angle. A second joining edge may be tilted to the vertical direction by a second vertical tilt angle. A maximum angular difference between the first vertical tilt angle and the second vertical tilt angle may be equal to or smaller than the off-axis angle. At least one (e.g., at least two or at least three) of the column sidewalls may be oriented along a respective one of the further main planes. In other words, at least one (e.g., at least two or at least three) of the column sidewalls may be completely formed in further main planes of the crystal lattice or in planes only slightly horizontally and/or slightly vertically tilted to further main planes of the crystal lattice. The term “slightly tilted” includes angular deviations from a respective main plane in the range of less than 5 degrees in any spatial direction.

For example, at least one (e.g., one, two, three, four, five or six) column sidewall is oriented in or along a plane of the {11-20} family of lattice planes, wherein, if more than one sidewall is oriented in or along a plane of the {11-20} family of lattice planes, each column sidewall is oriented in or along a different one of the planes of the {11-20} family of lattice planes. According to another example, at least one (e.g., one, two, three, four, five or six) column sidewall is oriented in or along a plane of the {1-100} family of lattice planes, wherein, if more than one sidewall is oriented in or along a plane of the {1-100} family of lattice planes, each column sidewall is oriented in or along a different one of the planes of the {1-100} family of lattice planes. According to yet another example, one or more of the column sidewalls may be oriented to a plane of the {11-20} family of lattice planes and at least one further column sidewall may be oriented in or along one of the planes of the {1-100} family of lattice planes.

The gate trenches may pattern the first portion of the silicon carbide substrate into ridges. By way of example, at least one of the sidewalls of the gate trenches and the ridges may be parallel to the (1-100) or the (−1100) planes.

The transistor may further comprise a source region of a first conductivity type, a channel region of a second conductivity type, and a drift region of the first conductivity type. For example, the first conductivity type may be n-type, and the second conductivity type may be p-type. According to further examples, the first conductivity type may be p-type and the second conductivity type may be n-type.

The source region, the channel region and part of the drift region may be arranged in the ridges. A current path from the source region to the drift region may extend in a depth direction of the silicon carbide substrate. As has been discussed above, the depth direction may be a direction which is different from a lateral or horizontal direction. For example, the depth direction may have a component which is perpendicular to the lateral direction. For example, the depth direction may be slanted with respect to the vertical direction. The transistor may further comprise a body contact portion of the second conductivity type that is arranged in a second portion of the silicon carbide substrate.

The second portion may be directly adjacent to the first portion. For example, a plurality of first and the second portions may be arranged alternately in the first direction. The second portion may extend in a second horizontal direction intersecting the first horizontal direction. The body contact portion may be electrically connected to the channel region. The body contact portion may further extend in the depth direction of the silicon carbide substrate to a portion below a bottom side of the gate trenches. The body contact portion may be directly adjacent to the drift region.

In this way, a shielding portion of the second conductivity type may extend from a side adjacent to a first main surface of the silicon carbide substrate to the drift zone. The shielding portion may be at a lateral distance to the gate electrode. In other words, the shielding portion may be laterally separated from the gate structure. A part of the shielding portion may be formed between the gate structure and the second surface of the silicon carbide body.

The shielding portion may contribute to shielding a gate dielectric against an electric potential that may be applied at the back side of the silicon carbide body. In a blocking mode of the silicon carbide device, the shielding portion may reduce the electric field in the gate dielectric and may thus contribute to increasing device reliability.

Transistors described herein may specifically include IGFETs (“insulated gate field effect transistor”). IGFETs are voltage controlled devices including MOSFETs (“metal oxide semiconductor FETs”) and other FETs comprising gate electrodes based on doped semiconductor material and/or comprising gate dielectrics that are not or not exclusively based on an oxide. As is to be clearly understood, further transistors may relate to IGBTs (“insulated gate bipolar transistor”).

The body contact portion may be connected to a source terminal. For example, the body contact portion may be connected to the source terminal via contact elements. The contact elements may e.g. be arranged in the second portion.

By way of example, a lateral extension of each of the contact elements in the second horizontal direction may be larger than a width of each of the ridges in the second horizontal direction. As a consequence, the formation of ohmic contacts which may be challenging for silicon carbide based semiconductor devices, may be simplified even when the width of the ridges is reduced.

According to an example, the ridges may extend through the second portion. More specifically, the ridges may be formed as continuous lines. In this way, the part of the ridges in the second portion may be used for forming an electrical contact between the source region and a source contact.

According to further examples, the ridges may be formed as parts of loops that extend to an edge region of the second portion. Accordingly, an electrical contact between the ridge and the second portion may be accomplished in the edge region. The ridges may be absent from a contact region in the second portion. The contact elements may be arranged in the contact region. In this way, a lateral dimension of the contact elements may be different from a pitch between the ridges. In more detail, a lateral dimension of the contact elements in the second direction may be larger than a width of the gate trenches.

For example, the ridges may be formed as parts of loops which are interrupted in an interruption portion between adjacent second portions. For example, one or two interruption portions may interrupt one loop. A gate contact may be disposed in the interruption portion. For example, one gate contact may be disposed in the interruption portion of one loop. According to further examples, one gate contact may be arranged in two interruption portions of one loop. According to still further examples, one gate contact may be arranged in the interruption portions of two adjacent loops.

The width of the ridge measured in the second direction may be arbitrary. According to examples, the width of the ridge may be narrow or ultra-narrow. For example, the term “ultra-narrow” may mean that the width is less than 100 nm. According to a further interpretation, the term “ultra-narrow” may mean that a width of each of the ridges is less than 4×L, wherein L denotes a length of a depletion zone at an interface between the channel region and an adjacent gate dielectric.

For example, the width of the depletion zone may be determined as:

$${l}_{d} = \sqrt{\frac{4 {ε}_{s} k T ln ( {N}_{A} / {n}_{i} )}{{q}^{2} {N}_{A}}}$$

wherein εₛ denotes the permittivity of the semiconductor material (9.66*ε₀ to 10.0*ε₀ for silicon carbide, depending on the crystal structure), k denotes the Boltzmann constant (1.38066*10⁻²³ J/K), T denotes the temperature, ln denotes the natural logarithm, NA denotes the impurity concentration of the semiconductor body, nᵢ denotes the intrinsic carrier concentration (e.g. 6.7*10⁻¹¹ cm⁻³ for silicon carbide at 27° C., strongly depending on the crystal structure), q denotes the elementary charge (˜1.6*10⁻¹⁹ C).

Generally, it is assumed that in a transistor the length of the depletion zone at a gate voltage corresponding to the threshold voltage corresponds to the maximum width of the depletion zone.

According to further interpretations, the term “ultra-narrow” may mean that a width of each of the ridges is less than 2×L. In this case the effective mobility of charge carriers can be increased by 5 to 18 times resulting in an improved performance of the device. In particular, due to the increased mobility of charge carriers some of the shortcomings of silicon carbide based semiconductors devices may be removed.

For example, an aspect ratio of height h to width d₁ of the ridges is larger than 7:1, e.g. approximately 10:1. For example, a width d₁ of the ridges may be between at least 25 nm and at most 60 nm and a height h of the ridges may be at least 300 nm to at most 700 nm. As a result, the channel length may be increased. Hence, short-channel effects such as DIBL (“Drain Induced Barrier Lowering”) may be reduced.

According to further examples, the semiconductor device may additionally comprise shielding structures of the second conductivity type, e.g. p-type, arranged below the gate trenches in the first portion of the silicon carbide substrate. A doping concentration of the shielding structures may be smaller than the doping concentration of the body contact portion. The shielding structures may be electrically connected to the body contact portion. The doping concentration and the lateral dimensions of these shielding structures are selected so that it is possible to fully deplete the shielding structures. For example, the field lines from the channel region to the shielding structures may be deflected. As a result, short channel effects such as DIBL may be further reduced.

The semiconductor device may further comprise buried tuning structures of the first conductivity type that may be arranged below the gate trenches in the second portion of the silicon carbide substrate. The buried tuning structures may be electrically connected to the drift region. The tuning structures may further modify the gate-drain and/or the gate-source capacitance and, hence, may improve the device characteristics.

As has been explained above, the lower region of the body contact portion may form a shielding portion. This shielding portion may be extended in the depth direction to form a doped column of the second conductivity type of a superjunction foundation. In this case the pitch between neighbouring doped columns may be optimized independently from the pitch of the ridges. For example, a distance t between a bottom portion of the body contact portion and a first main surface of the silicon carbide substrate is larger than 2 μm. For example, the distance t may be smaller than 30 μm. The distance t may depend on the voltage class for which the semiconductor device is to be used.

According to further examples, the body contact portion may extend to a drain region of the transistor.

For example, a trench extending in the second horizontal direction may be formed in the second portion of the silicon carbide substrate. A sidewall of the trench may be doped with dopants of the second conductivity type. According to further examples, all sidewalls of the trench may be doped with dopants of the second conductivity type. As a result, the body contact portion may extend to a deeper depth.

The contact elements, that may electrically connect the body contact portion to the source terminal, may be spatially separated from the source contacts electrically coupling the source region to the source terminal. By way of example, a conductive material of one of the contact elements, that may electrically connect the body contact portion to the source terminal, may be different from a conductive material of a source contact electrically coupling the source region to the source terminal. The terms “conductive material of the contact element” and “conductive material of a source contact” specifically refer to the conductive material that forms an ohmic contact to the silicon carbide and which is directly adjacent to the silicon carbide material. Accordingly, in case the contact elements or the source contact comprise a layer stack of different materials, the conductive materials in direct contact with the silicon carbide material may be different. Accordingly, the conductive material for forming an ohmic contact to silicon carbide material of the first conductivity type and the conductive material for forming an ohmic contact to silicon carbide material of the second conductivity type may be different. As a consequence, the ohmic contacts to silicon carbide material of the first and the second conductivity type may be independently optimized so as to improve the quality of the respective ohmic contacts.

Further layers of the contact elements and the source contact may be identical or different.

According to further examples, the gate electrode may comprise a first sublayer of a first conductive material in a lower portion of the gate trenches and a second sublayer of a second conductive material formed over the first sublayer, the second conductive material having a smaller resistivity than the first conductive material. For example, the first sublayer may be present in a portion of the gate trenches adjacent to the channel region. The first conductive material may, for example, be or comprise polysilicon. The second conductive material, may, for example, be or comprise a metal or a conductive metal oxide.

According to further examples, the gate electrode may comprise a single conductive material, for example, polysilicon, a metal or a conductive metal oxide.

A method of manufacturing a semiconductor device including a transistor may comprise forming gate trenches in a first portion of a silicon carbide substrate. The gate trenches may extend in a first horizontal direction and may pattern the first portion of the silicon carbide substrate into ridges. The method may further comprise forming a gate electrode in the gate trenches. The method may comprise forming a source region of a first conductivity type, a channel region of a second conductivity type, and a drift region of the first conductivity type. The source region, the channel region and a part of the drift region may be formed in the ridges. A current path from the source region to the drift region may extend in a depth direction of the silicon carbide substrate. The method may further comprise forming a body contact portion of the second conductivity type in a second portion of the silicon carbide substrate, the second portion being adjacent to the first portion. The second portion may extend in a second horizontal direction intersecting the first horizontal direction. The method may further comprise electrically connecting the body contact portion to the channel region. The body contact portion may be formed so as to extend in the depth direction of the silicon carbide substrate to a portion below a bottom side of the gate trenches and so as to be directly adjacent to the drift region.

For example forming the gate trenches may comprise a so-called double-patterning method to form small-sized portions of a hard mask layer. For example, forming the gate trenches may comprise forming a skeleton hard mask layer over the silicon carbide substrate and patterning the skeleton hard mask layer to a pattern of stripes. The method may further comprise conformally forming a hard mask layer over the patterned skeleton hard mask and anisotropically etching the hard mask layer to remove horizontal portions of the hard mask layer and to maintain vertical portions of the hard mask layer, thereby obtaining a hard mask. The method may further comprise removing the skeleton hard mask, etching portions of the silicon carbide substrate which are not covered by the hard mask, and removing remaining portions of the hard mask.

For example, the hard mask layer may be formed to have a thickness of less than 100 nm, e.g. less than 50 nm, e.g. some 10 nm. By way of example, conformally forming the hard mask layer may comprise performing an atomic layer deposition (“ALD”) method.

A material of the hard mask layer may be selected so as to be selectively etchable with respect to silicon carbide and the material of the skeleton hard mask layer. By way of example, the hard mask layer may comprise silicon oxide which may, for example, be etched by a highly anisotropic dry etching process.

The skeleton hard mask layer may comprise polysilicon which may be etched using a wet etching process.

After forming the gate trenches, a gate dielectric may be formed adjacent to sidewalls of the ridges. For example, the gate dielectric may be formed in the first and in the second portion of the silicon carbide substrate using the same processing method(s). As a result, a layer thickness of the gate dielectric in the first portion may be identical with the layer thickness of the gate dielectric in the second portion. According to further examples, the processing may be modified, e.g. by performing additional processing steps in the second portion. Due to this modification, a resulting layer thickness of the gate dielectric in the first portion may be different from the layer thickness of the gate dielectric in the second portion. The layer thickness of the gate dielectric may influence the gate-source capacitance and hence, a switching speed, for example. Hence, by changing the layer thickness of the gate dielectric in the second portion, the characteristics of the semiconductor device may be further modified.

According to a further example, a semiconductor device comprising a transistor may comprise a gate electrode arranged in gate trenches formed in a silicon carbide substrate and extending in a first horizontal direction. The gate trenches may pattern the silicon carbide substrate into ridges. The transistor may further comprise a source region of a first conductivity type, a channel region of a second conductivity type, a drift region of the first conductivity type, and a drain region of the first conductivity type. The source region may be arranged at a first main surface of the ridges, the drain region may be arranged at a second main surface of the silicon carbide substrate. The transistor may further comprise a body contact portion of the second conductivity type that may be arranged in a portion of the silicon carbide substrate extending in a second horizontal direction intersecting the first horizontal direction. The body contact portion may be electrically connected to the channel region. The body contact portion may extend in a depth direction of the silicon carbide substrate to a portion below a bottom side of the gate trenches and may be directly adjacent to the drift region.

A portion of the drift region may be arranged adjacent to the first main surface of the ridges. A further portion of the drift region may extend in a depth direction of the silicon carbide substrate. For example, a portion of the drift region may be arranged beneath the channel region. The drift region may extend to the drain region at the second main surface of the silicon carbide substrate

For example, the source region may be formed in a groove formed in the ridges. A doped portion of the second conductivity type may be adjacent to sidewalls and a bottom side of the groove, e.g. in a cross-section along the first direction. The channel region and the body contact portion may be arranged in the doped portions.

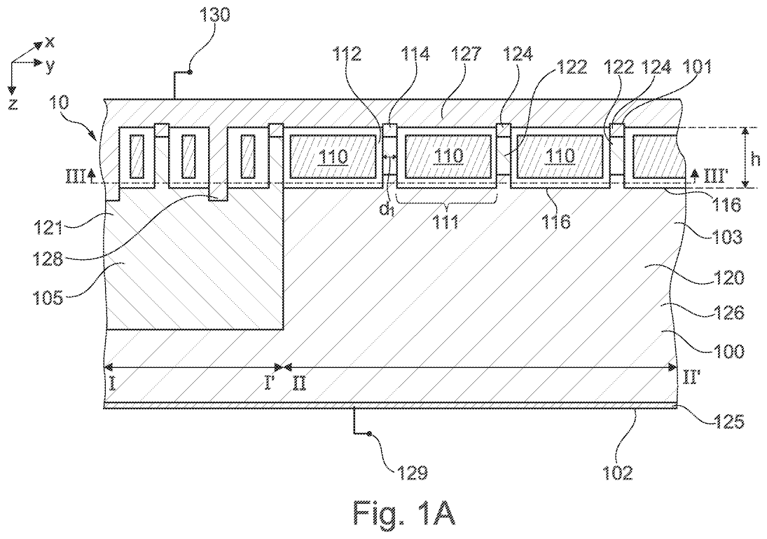

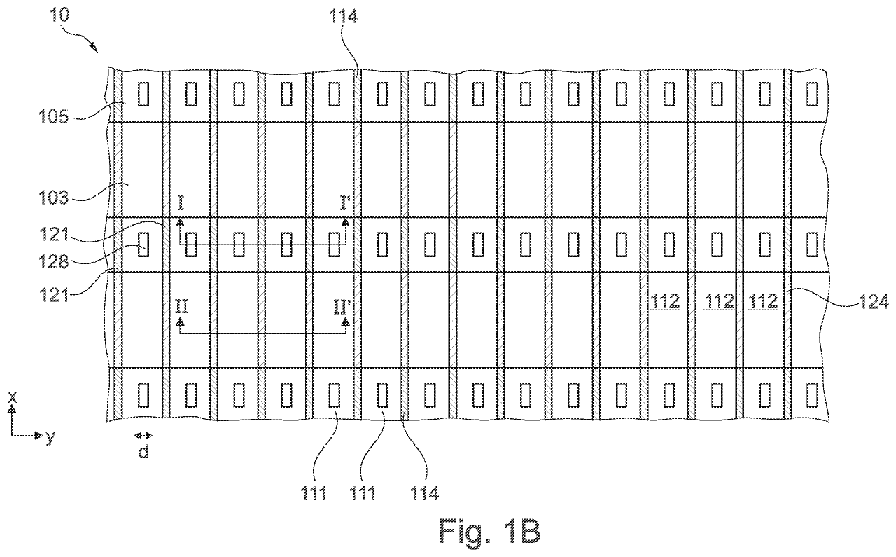

FIG. 1A shows merged cross-sectional views of portions of a semiconductor device 10 according to an example. In more detail, the right-hand portion of the cross-sectional view of FIG. 1A is taken between II and II′ in a first portion 103 of the silicon carbide substrate. The left-hand portion of the cross-sectional view of FIG. 1A is taken between I and I′ in a second portion 105 of the silicon carbide substrate.

As is further illustrated in FIG. 1B, a plurality of first portions 103 and second portions 105 may be arranged along a first horizontal direction, e.g. the x-direction. The second portion 105 may be directly adjacent to the first portion 103. The first portion and the second portion 105 may each extend along a second horizontal direction, e.g. the y-direction. Gate trenches 111 are formed in the first portion 103 of the silicon carbide substrate. The gate trenches 111 extend in the first horizontal direction. The gate trenches 111 pattern the first portion 103 of the silicon carbide substrate 100 into ridges 114.

Referring to FIG. 1A, a source region 124 of a first conductivity type is formed in an upper portion of the ridges 114. A channel region 122 of a second conductivity type is formed in a lower portion of the ridges 114. A part of the drift region 126 is arranged in a bottom portion of the ridges 114.

A further portion of the drift region 126 is arranged in a lower part of the silicon carbide substrate 100 below the gate trenches. The drift region may extend to a drain region 125 that is arranged at a second main surface 102 of the silicon carbide substrate. The drain region 125 may be doped with the first conductivity type. The gate electrode 110 is arranged in the gate trenches 111. The gate electrode 110 may be insulated from the channel region 122 by means of a gate dielectric 112. A thickness of the gate dielectric 112 in the first portion 103 may be identical with the thickness of the gate dielectric 112 in the second portion 105. According to further examples, the thickness of the gate dielectric 112 in the first portion 103 may be different from the thickness of the gate dielectric 112 in the second portion 105.

A body contact portion 121 of the second conductivity type may be arranged in a second portion 105 of the silicon carbide substrate. The body contact portion 121 is electrically connected to the channel region 122. The body contact portion 121 extends in the depth direction of the silicon carbide substrate to a portion below a bottom side 116 of the gate trenches 111. The body contact portion 121 is directly adjacent to the drift region 126. According to an example, the body contact portion 121 is electrically connected to a source terminal 130 via contact elements 128 that are arranged in the second portion 105.

The source region 114 may be connected to a source terminal 130. The drain region 125 may be electrically connected to a drain terminal 129.

By applying a suitable voltage to the gate electrode 110, the conductivity of a channel that is formed in the channel region 122 may be controlled. The gate electrode 110 is insulated from the channel region 122 by means of an insulating gate dielectric material 112 such as silicon oxide. By controlling the conductivity of a channel formed in the channel region 112, a current flow from the source region 114 via the channel region 122, to the drift zone 126 may be controlled. A current path from the source region to the drift region 126 extends in a depth direction of the silicon carbide substrate.

The body contact portion 121 may be doped at a higher doping concentration than the channel region 122. The channel region 122 is connected to the source terminal 130 via the body contact portion 121 in the second portion 105 of the silicon carbide and the contact element 128. As a result, a parasitic bipolar transistor is avoided which could be otherwise formed in this region.

As is further shown in FIG. 1A, the ridge 114 has a width di and a height h. For example, the gate electrode 110 may be disposed adjacent to at least two sides of the ridge 114. According to an embodiment, the following relationship holds for the width d₁ of the ridge 114:

d1≤4×L,

wherein L denotes a length of a depletion zone which is formed at the interface between the gate dielectric layer 112 and the channel region 122. For example, the width of each of the ridges may be less than 100 nm. According to further examples, the width of each of the ridges may be more than 20 nm. An aspect ratio of height h to width d₁ of the ridges may be larger than 7:1.

Due to the fact that the body contact portion 121 extends in the depth direction to a portion below a bottom side 116 of the gate trenches 111, the gate dielectric layer 112 is protected against high fields in an off-state of the device. In more detail, a JFET (Junction Field Effect Transistor) is formed at the interface between the body contact portion 121 and the drift region 126. Since, as is illustrated in FIG. 1B, the body contact portion 121 extends in the second horizontal direction intersecting the first horizontal direction, the pitch between adjacent gate trenches may be set independently from a lateral extension of the shielding structure. As a result, a pitch of the gate trenches may be reduced in comparison to the lateral dimension of the JFET shielding structure. Hence, pitch and lateral dimension may be optimized independently.

FIG. 1B shows a horizontal cross-sectional view of the semiconductor device shown in FIG. 1A. The cross-sectional view of FIG. 1B is taken between III and III′ as is illustrated in FIG. 1A. As is shown, the first portions 103 and the second portions 105 of the silicon carbide substrate are arranged alternately along the first direction. The gate trenches 111 pattern the silicon carbide substrate into ridges 114. The gate trenches 111 extend in the first horizontal direction. The ridges 114 also extend in the first horizontal direction.

As is illustrated in FIG. 1B, the ridges 114 may continuously extend in the first direction. The contact elements 128 are arranged between adjacent ridges 114 in the second portion 105 of the silicon carbide substrate. Accordingly, a width d of the contact element may be less than a width of the gate trenches 111 or the pitch between adjacent ridges 114.

As is illustrated in FIG. 1B, the ridges 114 continuously extend along the first direction.

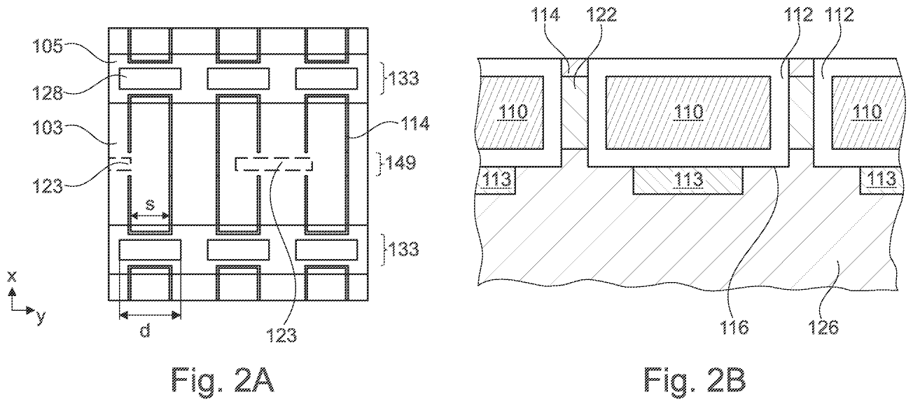

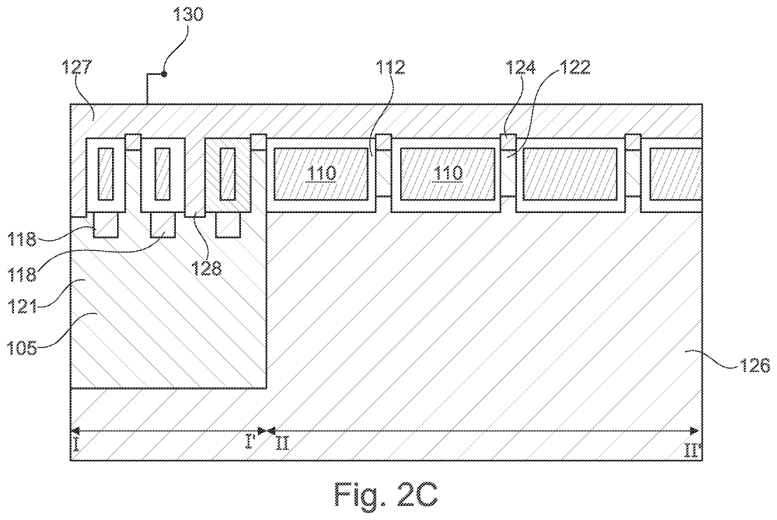

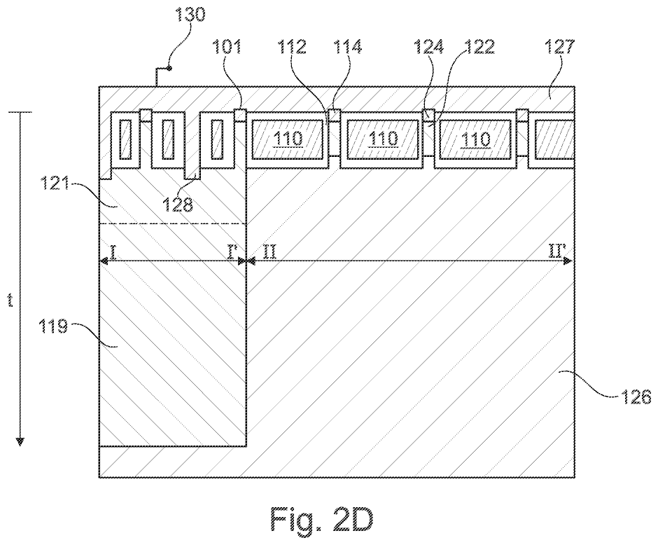

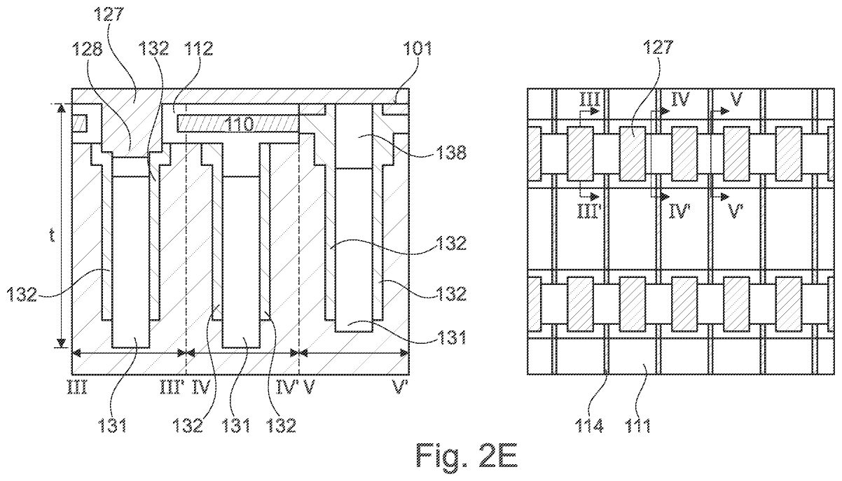

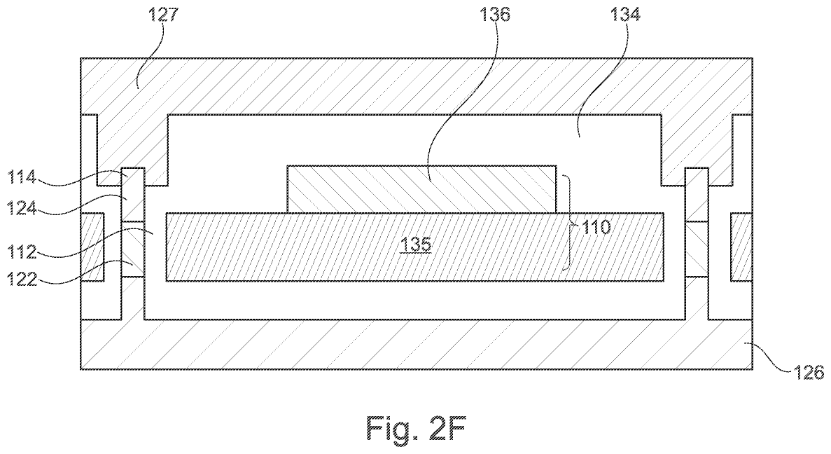

According to further embodiments, as is shown in FIG. 2A, the ridges 114 may extend in the first and in the second direction to form a loop or a part of a loop. As is shown, the ridges 114 may be absent from a contact region 133 in the second portion 105.

For example, the ridges 114 extend to an edge portion of the second portion 105 of the silicon carbide substrate. Then, they extend along the second direction and again extend along the first direction to the edge region of a neighboring second portion 105. The contact elements 128 may be arranged in the contact region 133, i.e. in the second portion 105 of the silicon carbide substrate between adjacent ridges 114.

As is further illustrated in FIG. 2A, the ridges 114 may be interrupted in an interruption portion 149 between adjacent second portions 105 of the silicon carbide substrate. A gate contact 123 may be arranged in the interruption portion 149. For example, as is illustrated in FIG. 2A, the gate contact 123 may be arranged so as to contact the gate electrode of two adjacent gate trenches. According to further examples, further interruption portions 149 may be provided for one loop. As a result, the gate contact 123 may be formed to extend in the second direction. Such a gate contact may contact the gate electrode in a plurality of gate trenches 111.

FIG. 2B shows a cross-sectional view of a portion of an example of a semiconductor device taken in the first portion 103 of the silicon carbide substrate 100. As is illustrated, shielding structures 113 of the second conductivity type are arranged below the gate trenches in the first portion 103 of the silicon carbide substrate. A doping concentration of the shielding structure 113 may be smaller than the doping concentration of the body contact portion 221. The shielding structures 113 are electrically connected to the body contact portion 121.

FIG. 2C shows a cross-sectional view of a further example of a semiconductor device. Components of the semiconductor device of FIG. 2C are similar to components of the semiconductor device illustrated in FIG. 1A. In addition, the semiconductor device further comprises buried tuning structures 118 of the first conductivity type that are arranged below the gate trenches 111 in the second portion 105 of the silicon carbide substrate. The buried tuning structures 118 are electrically connected to the drift region 126.

FIG. 2D shows a cross-sectional view of a further example of a semiconductor device. Components of the semiconductor device of FIG. 2D are similar to components of the semiconductor device illustrated in FIG. 1A. In addition, the body contact portion extends to a larger depth than is illustrated in FIG. 1A and forms a doped column of a superjunction structure. For example, a distance t between a bottom portion of the body contact portion 121 and a first main surface 101 of the silicon carbide substrate 100 may be larger than 2 μm. The body contact portion 121 may comprise a second portion 119 which has a lower doping concentration than the upper portion of the body contact portion 121. The upper portion may have a smaller distance to the first main surface 101 of the ridge than the second portion 119. The depth t may be smaller than 30 μm. According to this example, a p-doped column of a superjunction foundation may be formed in the second portion 105 of the silicon carbide substrate.

FIG. 2E shows various cross-sectional views of the second portion 105 of the silicon carbide substrate. The respective positions of the cross-sectional view shown in the left-hand portion of FIG. 2E are illustrated in the layout view shown in the right-hand portion of FIG. 2E. In more detail, a body contact trench 131 extending in the second direction may be formed in the second portion 105 of the silicon carbide substrate. The body contact trench 131 may extend to the depth t illustrated in FIG. 2D. Sidewalls of the body contact trench 131 may be doped with dopants of the second conductivity type. In a region between III and III′, the source contact 127 may be arranged in an upper portion of the trench. The material of the gate electrode, e.g. polysilicon, may be formed in a portion between a contact 127 and a ridge 114 (i.e. between IV and IV′). Due to the absence of a channel region, the gate electrode 110 arranged in the second portion 105 implements a passive gate electrode. In a portion intersecting the ridge 114, i.e. between V and V′, an insulating filling 138 is arranged in the upper portion of the body contact trench 131. A sidewall 132 of the body contact trench is doped with dopants of the second conductivity type. Accordingly, a super-junction is implemented.

FIG. 2F shows a cross-sectional view of a further example of a semiconductor device. As is shown, the gate electrode may comprise a first sublayer 135 and a second sublayer 136. For example, the second sublayer 136 may have a higher conductivity than the first sublayer 135. For example, the material of the first sublayer 135 may be polysilicon. A material of the second sublayer 136 may be a metal layer or a layer of a conductive metal oxide. As a consequence, the conductivity of the gate electrode 111 may be increased.

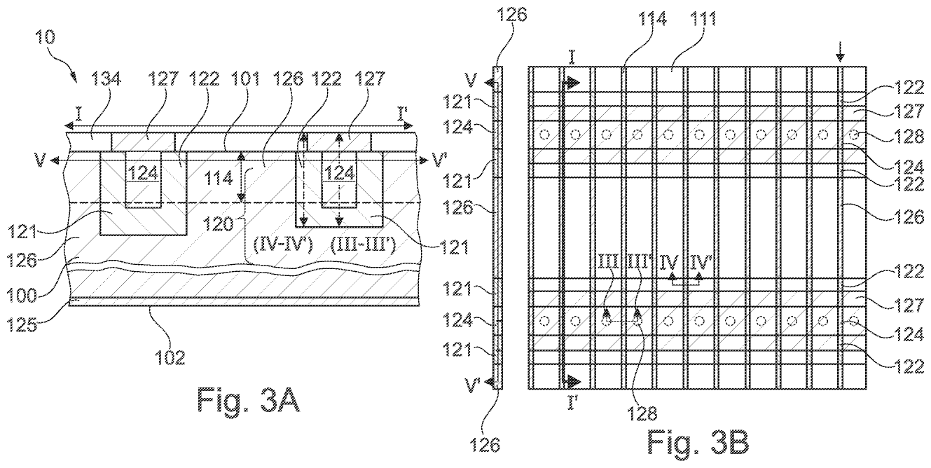

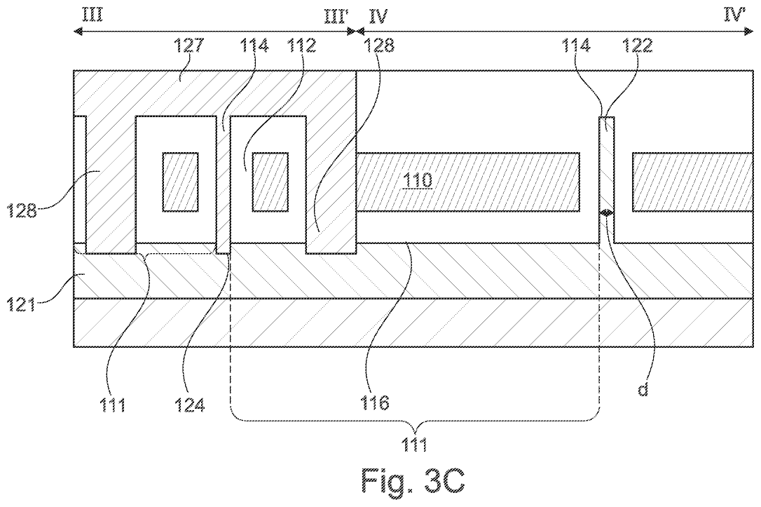

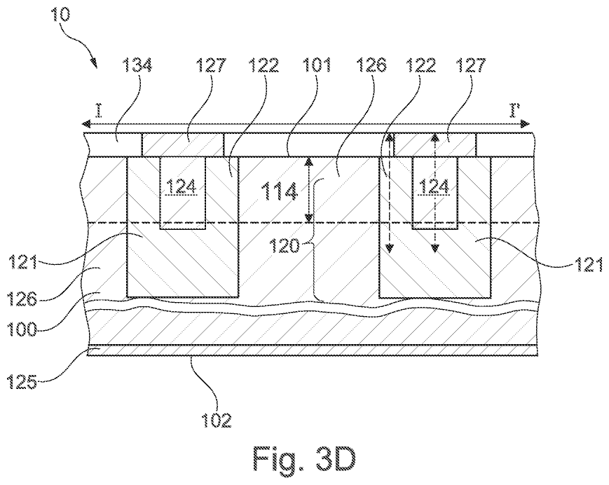

FIGS. 3A to 3D illustrate various views of a semiconductor device according to a further example. In particular, as will be discussed in the following, the example illustrated in FIGS. 3A to 3D implements a horizontal or a lateral transistor. FIG. 3B is a layout view of the semiconductor device illustrating the positions of the cross-sectional views of FIGS. 3A, 3C and 3D.

The cross-sectional view of FIG. 3A is taken in the first direction along a ridge 114. As is shown, the channel region 122 is arranged adjacent to a first main surface 101 of the ridge 114. In more detail, as is shown in FIG. 3A, the channel region 122 is arranged between the source region 124 and the drift region 126. Further, a portion of the drift region 126 is arranged so as to be adjacent to the first main surface 101 of the ridge 114. The source region 124 is formed in a groove enclosed by the channel region 122 and the body contact portion at a bottom side. The source region 124 is electrically connected to the body contact portion 121. For example, this may be accomplished via a source contact 127 that may be is formed so as to overlap the source regions 124 and the channel region 122. As will be explained with reference to FIG. 3C, a separate contact element 128 may be provided to electrically connect the source contact with the body contact portion 121. According to this implementation, it is not necessary that the source contact 127 overlaps channel region 122 and/or the body contact region 121.

When a suitable voltage is applied to the gate electrode, a conductive channel is formed in the channel region 122. As a consequence, a current path having a horizontal component is formed between the source region 124, the channel region 122, and the drift region 126. The current path further is formed between the drift region 126 and the drain region 125 and thus has a vertical component.

The body contact portion 121 that is formed at the bottom portion of the source region 124 further implements a shielding JFET for protecting the gate dielectric 112.

The right-hand portion of FIG. 3B shows a schematic layout of the components illustrated in FIG. 3A and further illustrates the direction of the cross-sectional views. In a corresponding manner as has been described before, the gate trenches 111 pattern the silicon carbide substrate into ridges 114. The source contact 127 may be formed so as to overlap the source regions 124 and the channel region 122. According to further examples, the source contact 127 does not overlap the channel region 122. Positions of contact elements 128 for electrically connecting the body contact portion 121 to the source contact 127 are illustrated in broken lines. These contact elements 128 may be used according to the example described with reference to FIG. 3D, e.g. when the source contact 127 does not overlap the channel region.

The left-hand portion of FIG. 3B shows a horizontal cross-section view that is taken between V and V′ for illustrating the doping profile.

FIG. 3C further shows merged cross-sectional views between III and III′. As is shown, between III and III′, the ridge 114 is arranged below a source contact 127 and extends in a depth direction between the source contact 127 and the body contact portion 121. The source contact 127 is electrically connected to the body contact portion 121 via contact portions extending in the depth direction.

A channel region 122 is arranged between IV and IV′. The width d of the ridges 114 may be chosen as has been explained above with reference to FIGS. 1A.

FIG. 3D shows a cross-sectional view of a semiconductor device which implements a lateral or horizontal transistor according to further examples. Elements illustrated in FIG. 3D are similar or identical to those illustrated in FIG. 3A. Differing from examples illustrated in FIG. 3A, the semiconductor device shown in FIG. 3D implements a superjunction device. As is illustrated, the body contact portion 121 extends to a larger depth than is illustrated in FIG. 3A and forms a doped column of a superjunction structure, in a similar manner as is illustrated in FIG. 2D.

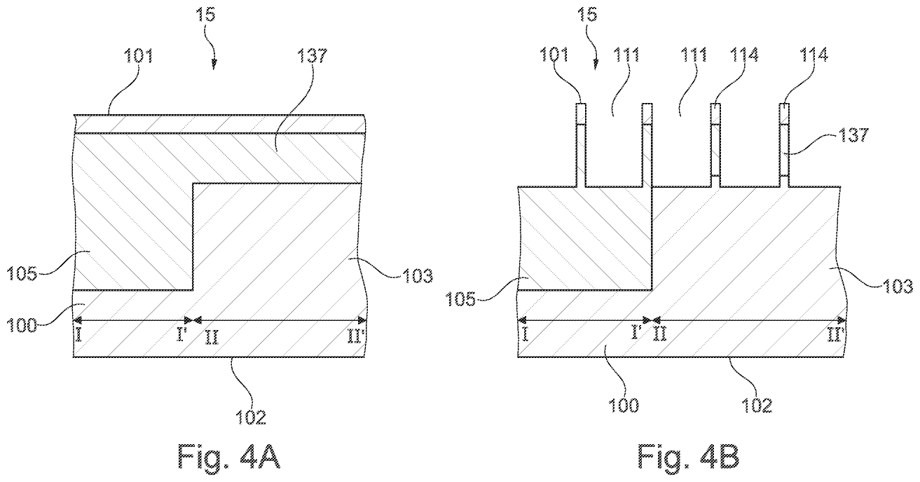

In the following, a method of manufacturing an example of the semiconductor device will be explained. Starting point is a silicon carbide substrate 100 that may be doped with dopants of the first conductivity type. Various implantation steps and activation steps are performed so as to provide differently doped regions. In more detail, as is shown in FIG. 4A, the workpiece may be doped so as to define a first portion 103 and a second portion 105. The positions of the different cross-sectional views of FIG. 4A may, for example, be taken from FIG. 1B.

A doped portion 137 of the second conductivity type is formed. For example, the doped portion 137 may extend in the second portion 105 to a deeper depth than the doped portion 137 in the first portion 103 of the silicon carbide substrate.

In a next step, a plurality of gate trenches 111 are formed. The gate trenches 111 are formed to pattern the silicon carbide substrate 100 into ridges 114. FIG. 4B shows an example of a resulting workpiece 15. As is shown, between II and II′, the trenches 111 extend to a position below a bottom side of the doped portion 137 of the second conductivity type. Between I and I′, the doped portion 137 of the second conductivity type extends to a position below the gate trenches 111.

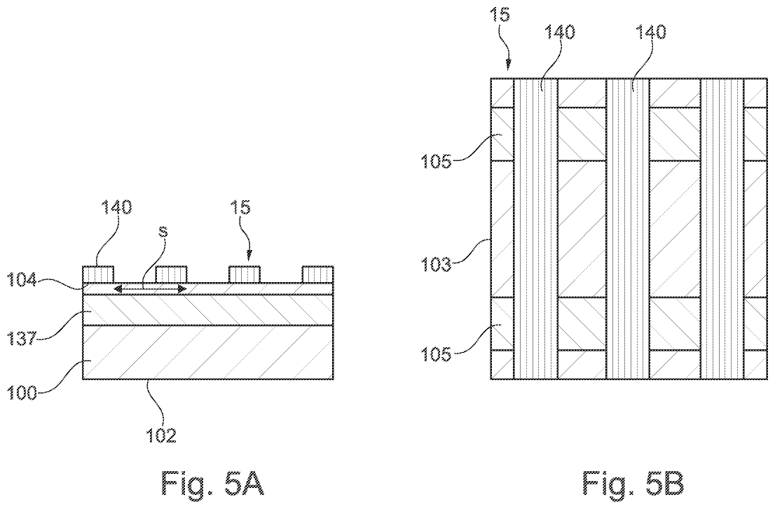

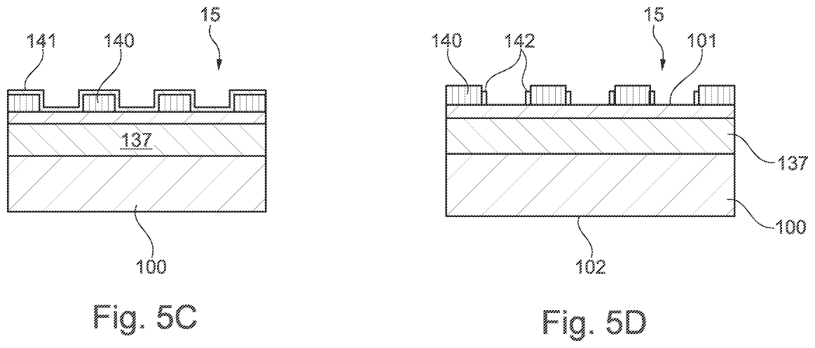

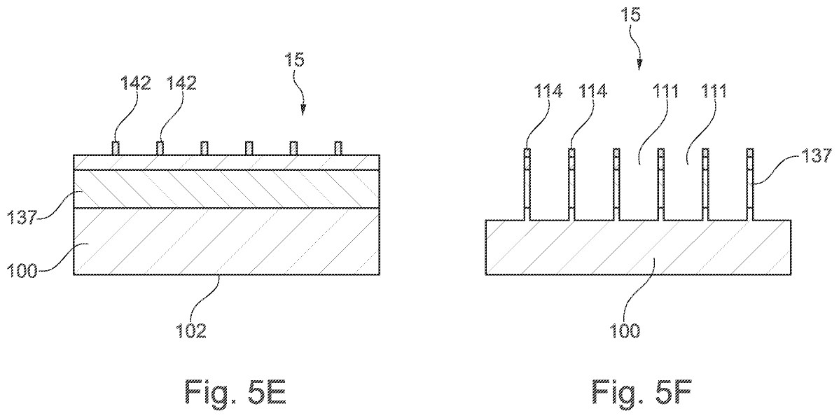

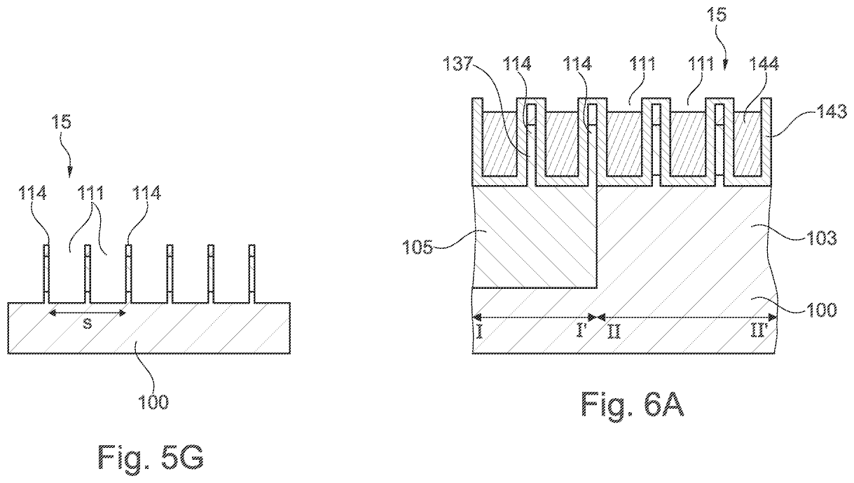

As has been discussed before with reference to FIG. 1A, the trenches may be dimensioned so that the ridges 114 have a very small width d. FIGS. 5A to 5G illustrate a double-patterning method of forming trenches 111 having small ridges 114 therebetween. Starting point for performing the double-patterning method is the workpiece 15 illustrated in FIG. 4A.

As is illustrated in FIG. 5A, a skeleton hard mask layer is formed over the first main surface 104 of a silicon carbide substrate. The skeleton hard mask layer is patterned to stripes so as to form a skeleton hard mask 140. The stripes of the patterned skeleton hard mask 140 may, e.g. have a pitch s. According to examples, a width of the stripes of the skeleton hard mask 140 may be equal to a distance between adjacent stripes. According to further examples, the width of the stripes of the skeleton hard mask 140 may be different from a distance between adjacent stripes.

FIG. 5B shows a layout view of a resulting workpiece 15. As is shown, the stripes of the patterned skeleton hard mask 140 extend in the first direction. The stripes may intersect the extension direction of the second portion 105 and of the first portion 103 of the silicon carbide substrate. A material of the skeleton hard mask layer may be selected so as to be selectively etchable with respect to silicon carbide.

In the next step (FIG. 5C), a hard mask layer 141 is formed over the resulting workpiece 15. The hard mask layer 141 may, for example, be formed using an ALD (“Atomic Layer Deposition”) method so as to obtain a hard mask layer 141 having a well-defined layer thickness. The hard mask layer 141 is formed as a conformal layer so as to have a constant thickness. For example, a thickness of the hard mask layer 141 may be in a range of some 10 nm. According to an example, the thickness of the hard mask layer 141 may be selected to be larger than a width of the ridges to be formed.

In the next step, a spacer etching method is performed so as to etch horizontal portions of the hard mask layer 141. As a result, the workpiece 15 as illustrated in FIG. 5D may be obtained. As is shown, the hard mask 142 now covers the sidewalls of the pattern skeleton mask layer 140.

In a next step, the skeleton hard mask layer 140 is removed from the workpiece. As a result, the workpiece 15 illustrated in FIG. 5E may be obtained. As is shown, the plurality of portions of the hard mask 142 having a width of some 10 nm may be formed over a surface of the workpiece.

Thereafter, an etching process may be performed using the hard mask 142 as an etching mask. As a result, the workpiece 15 shown in FIG. 5F may be obtained.

As is shown, the resulting ridges 114 have a very small width which is due to the precise control of the deposition of the hard mask layer 141.

Thereafter, residues of the hard mask 142 may be removed. As a result, the workpiece 15 shown in FIG. 5G may be obtained. As is illustrated, since the hard mask 142 has been formed as a spacer over the stripes of the skeleton hard mask 140, now two ridges 114 are formed within a pitch s of the skeleton mask 140. Depending on the width of the lines of the skeleton hard mask 140, the pitch of the ridges 114 may be equal to s/2. According to further examples, the distance between adjacent ridges may alternate, e.g. between two different values.

The following processing may be applied to the workpiece 15 e.g. shown in FIG. 5G or shown in FIG. 4B, independently of the width of the ridges 114 and the specific manner in which they have been produced.

After defining the ridges 114 and the gate trenches 111, further processing steps may be performed. For example, the gate trenches may be processed in an identical manner in the first portion 103 and the second portion 105 of the silicon carbide substrate 100. A dielectric layer 143 may be formed. For example, the dielectric layer 143 may be conformally formed. According to an example, the dielectric layer 143 may be formed in an identical manner in the first portion 103 and the second portion 105 of the silicon carbide substrate 100. As a result a layer thickness of the dielectric layer 143 may be identical in the first portion and the second portion of the silicon carbide substrate 100. According to a further example, the method for forming the dielectric layer 143 in the first portion may be different from the method for forming the dielectric layer 143 in the second portion 105, resulting in a different layer thickness.

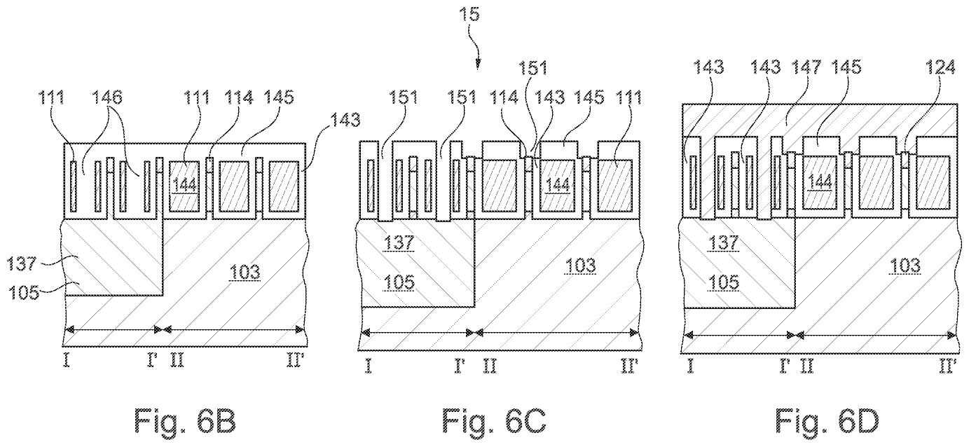

Further, a conductive layer 144, e.g. polysilicon, may be formed so as to fill the gate trenches 111. A recessing step may be performed so as to recess an upper portion of the conductive layer 144. FIG. 6A shows an example of a resulting workpiece 15.

Thereafter, contact openings 146 may be formed in the second portion 105 and an interlayer dielectric material 145 may be deposited. For example, the interlayer dielectric material 145 may comprise silicon oxide, silicon nitride or a combination of these materials. As is shown in FIG. 6B, as a result, the contact openings 146 are filled with the interlayer dielectric material 145. Further, an upper surface of the workpiece now is covered with the interlayer dielectric material 145.

Thereafter, second contact openings 151 are formed. In particular, second contact openings 151 are formed so as to expose a surface of the ridges 114 in the first portion 103 of the silicon carbide substrate. Moreover, second contact openings 151 are etched in the second portion 105 of the silicon carbide substrate. FIG. 6C shows an example of a resulting workpiece 15.

Thereafter, as is illustrated in FIG. 6D, a source metal layer 147 may be formed so as to provide an electrical contact to the source regions 124 in the first portion 103 of the silicon carbide substrate. Moreover, the source metal layer 147 may be formed over the second portion 105 so as to electrically contact the doped portion 137 of the second conductivity type.

Further processing steps, that are generally known, may be performed so as to finalize the semiconductor device that has been described above.

As has been explained above, the conductivity of the gate electrode 110 may be increased by additionally forming a second sublayer of the gate electrode having a higher conductivity. For example, starting from the workpiece 15 shown in FIG. 6A a gate metal layer 148 may be formed over the workpiece 15.

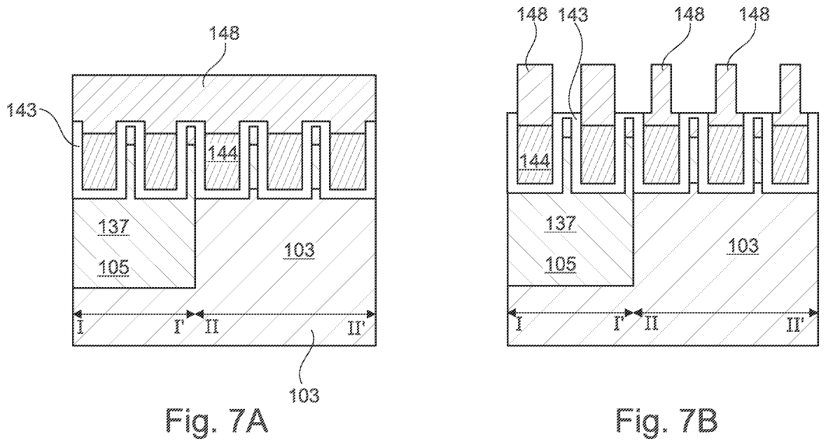

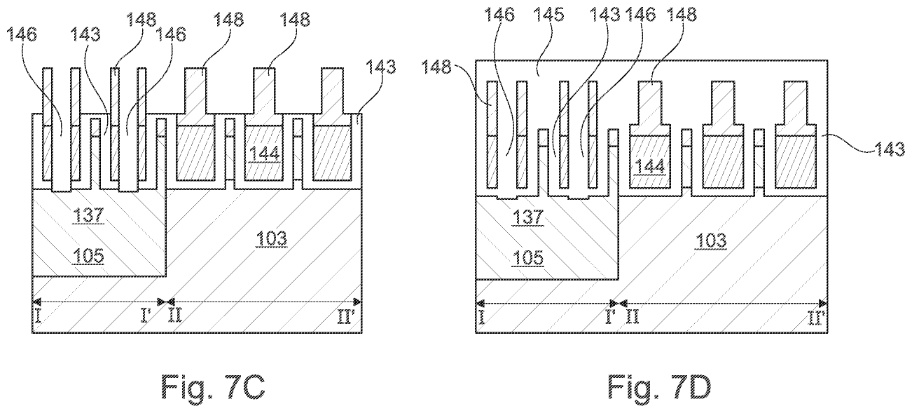

FIG. 7A shows an example of a resulting structure. As is shown, the gate metal layer 148 is formed so as to be in contact with the polysilicon layer 144 formed in the gate trenches 111.

Thereafter, the gate metal layer 148 is patterned. According to examples, the gate metal layer 148 is patterned so as to be present in the first portion 103 and in the second portion 105 of the silicon carbide substrate 103. According to further examples, the gate metal layer 148 may be patterned to be only present in one of the first portion 103 or second portion 105 of the silicon carbide substrate.

FIG. 7B shows an example of a resulting workpiece. Thereafter, contact openings 146 are formed in the second portion 105 of the silicon carbide substrate. The contact openings 146 extend to the doped portion 137 of the second conductivity type.

FIG. 7C shows an example of a resulting workpiece 15. Thereafter, an interlayer dielectric 145 is formed so as to fill the contact openings 146 as well as the spaces between adjacent patterned portions of the gate metal layer 148.

FIG. 7D shows an example of a resulting workpiece. As is seen, due to the contact openings 146 and the adjacent dielectric layer, it may be complicated to provide the gate metal layer 148 in the second portion 105 of the silicon carbide substrate. On the other hand, due to the narrow width of the conductive structures in the second portion 105, the gate metal layer 148 may greatly improve the conductivity of the gate electrode in the second portion 105. However, as is to be clearly understood, according to examples, the gate metal layer 148 may be only present in the first portion 103 and may be omitted from the second portion 105 of the silicon carbide substrate.

Thereafter, the further processing steps that have been explained with reference to FIGS. 6C and 6D may be performed.

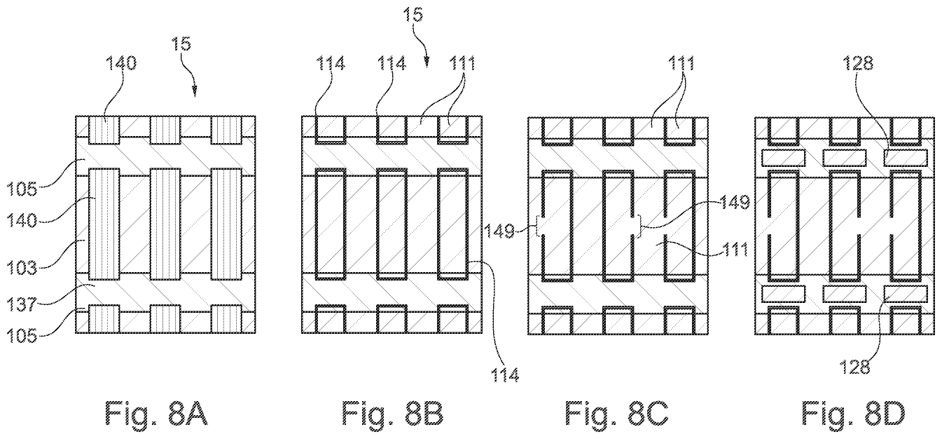

FIGS. 8A to 8D illustrate processing steps according to which the example shown in FIG. 2A may be manufactured. Starting from the workpiece that is illustrated in FIGS. 5A and 5B, the lines of the skeleton hard mask 140 may be interrupted in the second portion 105 of the silicon carbide substrate.

FIGS. 8A shows an example of a resulting workpiece 15. Thereafter, a hard mask layer 141 is formed, followed by a spacer etching process to form a hard mask 142 in a similar manner as has been described with reference to FIG. 5D. As a result, the hard mask 142 encloses the rectangles of the skeleton hard mask 140. After removing the skeleton hard mask 140, an etching process similar as has been described with reference to FIG. 5F is performed so as to define the gate trenches 114.

FIG. 8B shows an example of a workpiece 15, when the interrupted lines of the skeleton hard mask 140 are used for defining a mask for patterning the gate trenches 111. As is illustrated in FIG. 8B, closed loops of the ridges 114 may be formed. The ridges 114 extend to an edge region of the second portion 105 of the silicon carbide substrate.

Thereafter, as is shown in FIG. 8C, interruption portions 149 may be formed by etching portions of the ridges 114. As a consequence, the ridges 114 are interrupted at least at one portion of the loops. For example, the interruption portion 149 may be arranged so that interruption portions 149 of adjacent loops face each other.

FIG. 8C shows an example of a resulting structure. As is to be clearly understood, additional interruption portions 149 may be formed.

Thereafter, as is shown in FIG. 8D, contact elements 128 may be formed in the second portion 105 of the silicon carbide substrate. Further, gate contacts (not illustrated) may be formed in the interruption portions 149 of the loops of ridges at a later processing stage.

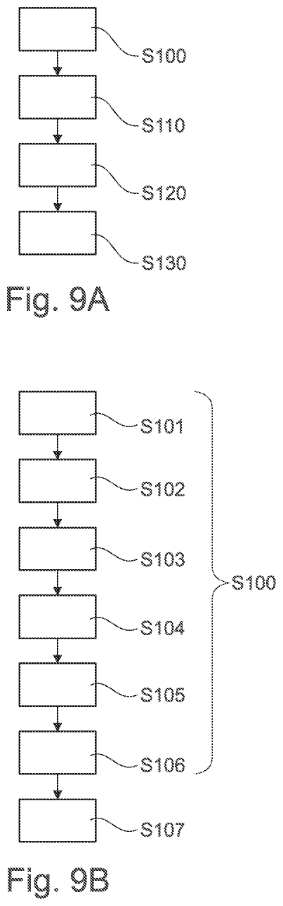

FIG. 9A summarizes a method according to examples. A method of manufacturing a semiconductor device comprising a transistor may comprise forming (S100) gate trenches in a first portion of a silicon carbide substrate, the gate trenches extending in a first horizontal direction and patterning the first portion of the silicon carbide substrate into ridges. The method may further comprise forming (S110) a gate electrode in the gate trenches, forming (S120) a source region of a first conductivity type, a channel region of a second conductivity type, and a drift region of the first conductivity type, the source region, the channel region and a part of the drift region being formed in the ridges, a current path from the source region to the drift region extending in a depth direction of the silicon carbide substrate. The method may additionally comprise forming (S130) a body contact portion of the second conductivity type in a second portion of the silicon carbide substrate, the second portion being adjacent to the first portion, the second portion extending in a second horizontal direction intersecting the first horizontal direction, comprising electrically connecting the body contact portion to the channel region, the body contact portion being formed so as to extend in the depth direction of the silicon carbide substrate to a portion below a bottom side of the gate trenches and so as to be directly adjacent to the drift region.

FIG. 9B summarizes an implementation of a processing for forming (S100) the gate trenches. Forming (S100) the gate trenches may comprise forming (S101) a skeleton hard mask layer over the silicon carbide substrate and patterning (S102) the skeleton mask layer to a pattern of stripes. The method may further comprise conformally forming (S103) a hard mask layer over the patterned skeleton hard mask layer. The method may additionally include anisotropically etching (S104) the hard mask layer to remove horizontal portions of the hard mask layer and to maintain vertical portions of the hard mask layer, thereby obtaining a hard mask, and removing (S105) the skeleton hard mask. The method may further comprise etching (S106) portions of the silicon carbide substrate which are not covered by the hard mask, and removing (S107) remaining portions of the hard mask.

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device comprising a transistor, the transistor comprising:
a gate electrode arranged in gate trenches formed in a first portion of a silicon carbide substrate and extending in a first horizontal direction, the gate trenches patterning the first portion of the silicon carbide substrate into ridges;
a source region of a first conductivity type, a channel region of a second conductivity type, and a drift region of the first conductivity type, the source region, the channel region and a part of the drift region being arranged in the ridges, a current path from the source region to the drift region extending in a depth direction of the silicon carbide substrate; and
a body contact portion of the second conductivity type that is arranged in a second portion of the silicon carbide substrate, the second portion being adjacent to the first portion, the second portion extending in a second horizontal direction intersecting the first horizontal direction, the body contact portion being electrically connected to the channel region, the body contact portion extending in the depth direction of the silicon carbide substrate to a portion below a bottom side of the gate trenches and being directly adjacent to the drift region.

2. The semiconductor device of claim 1, wherein the body contact portion is connected to a source terminal via contact elements arranged in the second portion.

3. The semiconductor device of claim 2, wherein a lateral extension of each of the contact elements in the second horizontal direction is larger than a width of each of the ridges in the second horizontal direction.

4. The semiconductor device of claim 2, wherein the ridges extend to an edge region of the second portion and are absent from a contact region in the second portion, the contact elements being arranged in the contact region.

5. The semiconductor device of claim 4, wherein the ridges are interrupted in an interruption portion between adjacent second portions, further comprising a gate contact in the interruption portion.

6. The semiconductor device of claim 2, wherein a conductive material of one of the contact elements is different from a conductive material of a source contact electrically coupling the source region to the source terminal.

7. The semiconductor device of claim 1, wherein the ridges extend through the second portion.

8. The semiconductor device of claim 1, wherein a width of each of the ridges is less than 100 nm.

9. The semiconductor device of claim 1, wherein a width of each of the ridges is less than 4×L, and wherein L denotes a length of a depletion zone at an interface between the channel region and an adjacent gate dielectric.

10. The semiconductor device of claim 1, wherein an aspect ratio of height to width of the ridges is larger than 7:1.

11. The semiconductor device of claim 1, further comprising shielding structures of the second conductivity type arranged below the gate trenches in the first portion of the silicon carbide substrate, a doping concentration of the shielding structures being smaller than the doping concentration of the body contact portion, the shielding structures being electrically connected to the body contact portion.

12. The semiconductor device of claim 1, further comprising buried tuning structures of the first conductivity type arranged below the gate trenches in the second portion of the silicon carbide substrate, the buried tuning structures being electrically connected to the drift region.

13. The semiconductor device of claim 1, wherein a distance between a bottom portion of the body contact portion and a first main surface of the silicon carbide substrate is larger than 2 μm.

14. The semiconductor device of claim 1, wherein the body contact portion extends to a drain region of the transistor.

15. The semiconductor device of claim 1, further comprising a body contact trench formed in the second portion of the silicon carbide substrate, the body contact trench extending in the second horizontal direction, wherein a sidewall of the body contact trench is doped with dopants of the second conductivity type.

16. The semiconductor device of claim 1, wherein the gate electrode comprises a first sublayer of a first conductive material in a lower portion of the gate trenches and a second sublayer of a second conductive material formed over the first sublayer, the second conductive material having a smaller resistivity than the first conductive material.

17. A method of manufacturing a semiconductor device comprising a transistor, the method comprising:
forming gate trenches in a first portion of a silicon carbide substrate, the gate trenches extending in a first horizontal direction and patterning the first portion of the silicon carbide substrate into ridges;
forming a gate electrode in the gate trenches;
forming a source region of a first conductivity type, a channel region of a second conductivity type, and a drift region of the first conductivity type, the source region, the channel region and a part of the drift region being formed in the ridges, a current path from the source region to the drift region extending in a depth direction of the silicon carbide substrate; and
forming a body contact portion of the second conductivity type in a second portion of the silicon carbide substrate, the second portion being adjacent to the first portion, the second portion extending in a second horizontal direction intersecting the first horizontal direction, comprising electrically connecting the body contact portion to the channel region, the body contact portion being formed so as to extend in the depth direction of the silicon carbide substrate to a portion below a bottom side of the gate trenches and so as to be directly adjacent to the drift region.

18. The method of claim 17, wherein forming the gate trenches comprises:
forming a skeleton hard mask layer over the silicon carbide substrate and patterning the skeleton hard mask layer to a pattern of stripes;
conformally forming a hard mask layer over the patterned skeleton hard mask;
anisotropically etching the hard mask layer to remove horizontal portions of the hard mask layer and to maintain vertical portions of the hard mask layer, thereby obtaining a hard mask;
removing the skeleton hard mask;
etching portions of the silicon carbide substrate which are not covered by the hard mask; and
removing remaining portions of the hard mask.

19. The method of claim 18, wherein the hard mask layer is formed to have a thickness of less than 100 nm.

20. The method of claim 18, wherein conformally forming the hard mask layer comprises performing an atomic layer deposition method.

21. A semiconductor device comprising a transistor, the transistor comprising:
a gate electrode arranged in gate trenches formed in a silicon carbide substrate and running in a first horizontal direction, the gate trenches patterning the silicon carbide substrate into ridges;
a source region of a first conductivity type, a channel region of a second conductivity type, a drift region of the first conductivity type, and a drain region of the first conductivity type, the source region being arranged at a first main surface of the ridges, the drain region being arranged at a second main surface of the silicon carbide substrate; and
a body contact portion of the second conductivity type that is arranged in a portion of the silicon carbide substrate extending in a second horizontal direction intersecting the first horizontal direction, the body contact portion being electrically connected to the channel region, the body contact portion extending in a depth direction of the silicon carbide substrate to a portion below a bottom side of the gate trenches and being directly adjacent to the drift region.

22. The semiconductor device of claim 21, wherein the drift region is arranged adjacent to the first main surface of the ridges.

23. The semiconductor device of claim 21, wherein the source region is formed in a groove formed in the ridges, a doped portion of the second conductivity type being adjacent to sidewalls and a bottom side of the groove, the channel region and the body contact portion being arranged in the doped portions.
